(19) United States
(12) Patent Application Publication
(10) Pub. No.: US 2011/0065240 A1
(43) Pub. Date: Mar. 17, 2011

(54) LEAD FRAME AND METHOD OF FORMING SAME

(75) Inventors: Xu GAO, Tlanjin (CN); Qingchun He, Tianjin (CN); Nan Xu, Tianjin (CN)

(73) Assignee: FREESCALE SEMICONDUCTOR, INC, Austin, TX (US)

(21) Appl. No.: 12/578,556

(22) Filed: Oct. 13, 2009

(30) Foreign Application Priority Data
Sep. 14, 2009 (CN) 200910173172

(51) Int. Cl. H01L 21/60; H01L 23/495; B21D 31/02

(52) U.S. Cl. 438/110; 257/666; 72/327; 257/E21.506; 257/E23.031

(57) ABSTRACT

A lead frame and a method of making a lead frame for a semiconductor package. The lead frame is formed by stamping a lead frame material into a desire configuration. The stamped lead frame is then affixed to a support material. When assembling a semiconductor package using the lead frame, during saw singuation, the saw does not have to cut through much lead frame material. Thus, the saw blade does not wear quickly.

### BACKGROUND OF THE INVENTION

This invention relates generally to an apparatus and method of a lead frame for a semiconductor device, and more particularly to a supported stamped lead frame for use in a semiconductor device such as for example an area mounting type semiconductor device.

Recent developments in semiconductor device technology have been made to achieve ever smaller size and scale of semiconductor devices and reach ever higher device performances. In view of the smaller scale and size of components achievable, the component densities in semiconductor dies and packages have increased. Consequently, the advancements in semiconductor device technology has outpaced the advances made in semiconductor packaging technology. Although the scale of the individual semiconductor components has reduced, there still remains a scarcity of space for semiconductor components within a semiconductor device package.

However, one aspect of semiconductor devices that has remained by comparison for the most part relatively unchanged in the recent developments is lead frame design. Typically, conventional lead frame design does not lend itself to the other advancements made in the smaller scale and size of components. For example, typically in the formation of lead frames in area mounting type semiconductor devices in design and package assembly such as quad flat pack no-lead (QFN), small-outline no leads (SON) leadless integrated circuit (IC) packages have connections made to the devices via contacts on the bottom side of the component to the surface of the connecting substrate of the printed circuit board (PCB). Due to the brittle or pliable nature of lead frame material, conventional lead frames may only be designed having lead sections with a minimum thinness or narrowness as such thin or narrow lead frame sections are susceptible to bending or displacement during the processing environment of the semiconductor device. Conventional lead frame design does not typically easily allow a designer to select any desired configurations for lead positions beyond the limited number of conventional lead designs. For example, in configurations where half etch lead frame is implemented, it is difficult to achieve desired lead configuration under typical lead frame design as it is not possible to reach half etch with the lead frame with a conventional lead frame. Conventional techniques and designs in the placement of leads of a lead frame are not suitable for the new requirements in the industry.

Thus, there is a need to extend conventional lead frame technology to allow many desired lead position configurations while maximizing space in semiconductor package assemblies.

### BRIEF DESCRIPTION OF THE DRAWINGS

In order that embodiments of the invention may be fully and more clearly understood by way of non-limitative examples, the following description is taken in conjunction with the accompanying drawings in which like reference numerals designate similar or corresponding elements, regions and portions, and in which:

FIG. 1 pictorially shows lead frame manufacturing in accordance with an embodiment of the invention;

FIG. 2A-2D shows cross-sectional view of a punch and a die for forming a lead frame in different steps of the process in accordance with an embodiment of the invention;

FIG. 3 is a flow chart in accordance with a method of an embodiment of the invention;

FIG. 4A-4C shows lead frame after stamping process (FIG. 4A), after wire bond (FIG. 4B) and after molding (FIG. 4C) in accordance with an embodiment of the inventions;

FIG. 5A-5B show areas of the lead frame after wire band in greater detail of areas A (FIG. 5A) and B (of FIG. 5B) as indicated in FIG. 3B in accordance with an embodiment of the invention; and

FIG. 6 shows the lead frame after molding of FIG. 4C in greater detail in accordance with an embodiment of the invention.

### DETAILED DESCRIPTION OF THE INVENTION

An apparatus and method for a supported, stamped lead frame for use in a semiconductor device. Such devices include quad flat pack no-lead (QFN)/power quad flat pack no-lead (PQFN) integrated circuit (IC) devices and the like. By adding a support or tape during the stamping of the lead frame process, the supported/taped stamping lead frame undergoes assembly processing including die bond wire bonding, molding and saw singluation without metal or other supporting structure in the saw street during processing. As there is no required metal in saw street, the saw blade life also increases.

An aspect of the invention provides a method of fabricating a lead frame, the method comprising stamping a lead frame material into a desired lead frame configuration; and supporting the stamped lead frame material with a support material.

In an embodiment the support material is adhered together with the stamped lead frame material. The support material may be adhered to the stamped lead frame material.

An aspect of the invention provides a method of processing a semiconductor device having a lead frame, the method comprises stamping a lead frame material into a desired lead frame configuration; supporting the stamped lead frame material with a support material; die bonding a semiconductor die on the lead frame; wire bonding with wires the semiconductor die with the lead frame; molding the lead frame, semiconductor die, and wires to form the semiconductor package with the support material; removing the support material; and singulating the units of the semiconductor device forming unit semiconductor devices.

An aspect of the invention provides an apparatus for fabricating a lead frame, the apparatus comprises a punch having a surface for stamping a lead frame; a die for a desired lead frame configuration, the die having edges for defining a desired lead frame configuration; and a lead frame material receiving area for receiving the lead frame material between the surface of the punch and the edges of the die; and a support material receiving area for receiving a support material for supporting the desired lead frame configuration stamped by punch.

An aspect of the invention provides a lead frame comprising a lead frame material stamped into a desired lead frame configuration; and a supporting material to support the lead frame.

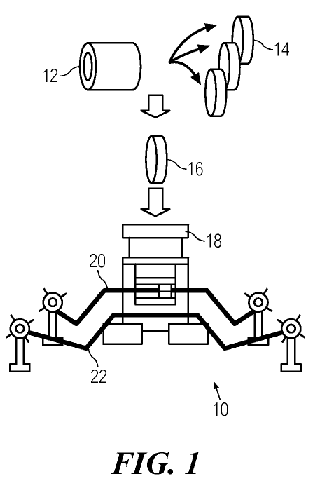

Referring to FIG. 1, an apparatus 10 is shown for stamping a lead frame from lead frame material 20. The lead frame material may be formed from a master coil 12, master coil units 14, and/or single coil units 16. Such lead frame materials may be copper, and the like for example copper or copper material types such as copper CDA 194 ES, and other alloys such as alloy 42 and the like. The apparatus 10 further comprises a stamping device 18 for stamping the lead frame material into the desired shape and configuration. The apparatus also holds a tape material 22 and is arranged such that when the lead frame is stamped by the stamping device the stamped lead frame is fixed directly onto the surface of the support or tape material. The support may be for example acrylic tape, silicon tape and the like.

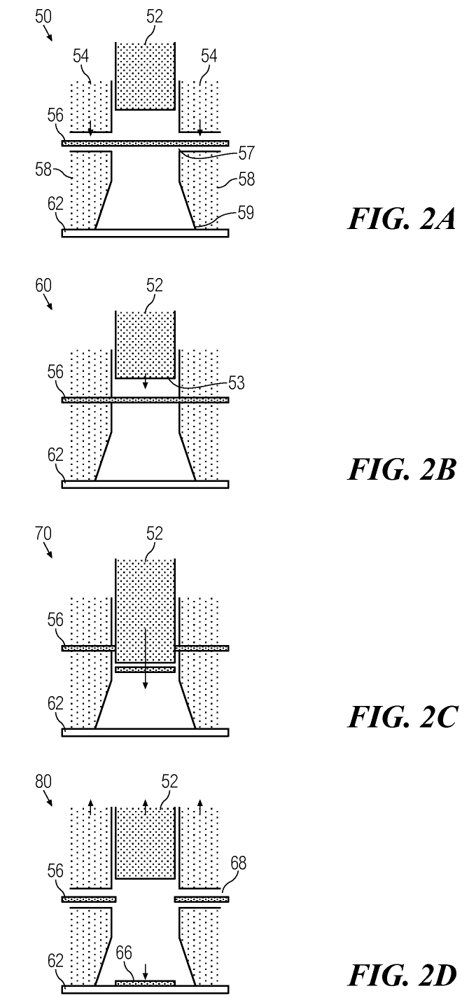

FIG. 2A-2D show cross-sectional view of the interaction between the punch and the die apparatus in the process of forming a lead frame during different steps of the process in accordance with an embodiment of the invention. In FIG. 2A shows a cross-sectional view of the lead frame stamping and support or taping device at an idle start 50. The device comprises a punch 52 and stripper 54 that are arranged above the lead frame material 56. The lead frame material 56 is positioned below the punch 52 and above a die 58. The edges 57 of the die form the shape and form of the desired lead frame. The internal sides 59 of the die are flared or tapered away from the edges 57 to ensure that the lead frame avoids contact with the side of the die during processing. The support or tape 62 is positioned below the die 58 under the lead frame material 56 and the punch 52.

In FIG. 2B the lead frame stamping and taping device is shown as the punch starts the stroke process 60 and the punch drops or moves downward along the stripper 55.

In FIG. 2C the punch 52 punches 70 the lead frame material 56 with the surface 53 of the punch and the edges of the die 58 to form the desired lead frame 64. The punch and continues to stroke downward past the edges 57 of the die and past the sides 59 of the die.

In FIG. 2D the punched lead frame 64 is placed on the tape 62 and the lead and flag 66 of the lead frame is formed. The lead frame material 56 that does not form part of the punched lead frame 64 is scrap 56. The punched lead frame 64 is fixed to the support 62.

The support 62 supports the punched lead frame 64. The support may take different forms, for example, the support may be tape, a substrate, a carrier and the like. Other types of supports may be for example acrylic tape, silicon tape and the like. The lead frame is punched off from the coil and attached to the support. Where the support is a tape, the tape has an adhesive that fixes the punched lead frame 64 to the tape.

The lead frame in accordance with embodiments of the invention may be designed having thinner or narrower leads than previously achievable. Also, with embodiments of the invention, lead frames may be fabricated for area mounting type semiconductor devices. For example, the lead frames may be arranged in a package assembly such as quad flat pack no-lead (QFN), small-outline no leads (SON) leadless integrated circuit (IC) packages and have connections made to the devices via contacts on the bottom side of the component to the surface of the connecting substrate of the printed circuit board (PCB). As the lead frame is supported by support or tape 62, the lead frame material is supported to withstand movement or displacement during the processing and package assembly of the semiconductor device package. With embodiments of the invention, the lead frame may be designed to any desired configurations for lead positions having a minimum thickness of lead frame material. Accordingly, the lead frame in accordance with embodiments of the invention may be configured, for example, in half etch lead frame.

The support provides support to the punched lead frame to ensure that the lead frame maintains the desired shape of the punched lead frame during semiconductor device processing. By providing the additional support to the punched lead frame during processing the design of the lead frame may be made more precise and intricate. The lead frame may be arranged thinner than was achievable by conventional lead frames using the same material since the material is supported.

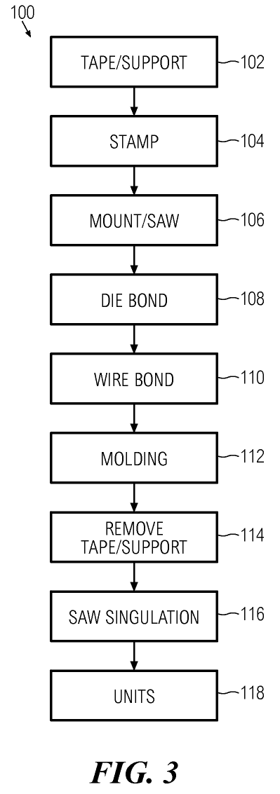

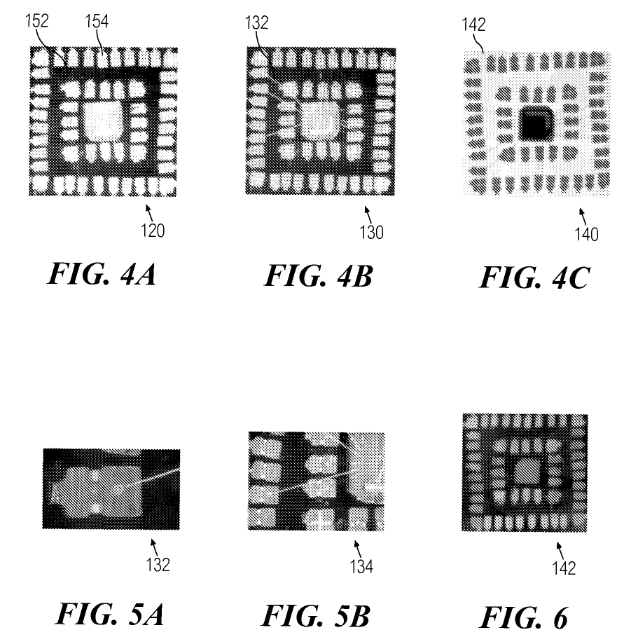

FIG. 3 shows a method 100 in accordance with an embodiment of the invention. The method shows that the lead frame is stamped or punched 102 and then placed 104 on a carrier or support such as tape. It will be appreciated that the lead frame can be fixed to the support prior to stamping. The substrate that forms the dies for the semiconductor devices is mounted and sawed 106 for forming the dies. The dies are bonded 108 and wire bonded 110 in place with the lead frame. The semiconductor components such as the lead frame, dies, and wires are then molded 112 for the packaging process. The carrier such as tape is removed 114 from the semiconductor package assembly. Saw singulation 116 is performed on the semiconductor package assembly to form individual units 118.

By adding the support or taping process in the stamping lead frame procedure, the lead and flag for individual units may be formed and then the lead frame individual unit is attached directly to the support such as the tape. When the supported stamped lead frame reaches an assembly factory, and goes through the die bond wire bond processing, molding and saw singulation, saw blade life is maximized because there is no metal in saw street. Additionally, as there is no metal in the saw street, only the molding compound is sawed during saw singulation which prevents high temperatures from being reached during saw singulation. By maintaining a lower temperature during saw singulation, saw life is extended as high temperature during saw singulations induces saw blades to wear out. In conventional designs the metal is in the saw street to provide strong physical connection and stability of the individual units during the assembly process. In accordance with embodiments of the invention the additional metal in the saw street is not required as the support provides stability during the assembly process. Advantageously, as there is no metal in the saw street in embodiments of the invention, the material and manufacturing cost of the lead frame is minimized and lower than conventional designs. Additionally, embodiments of the invention provide flexible lead layout and design, and increased capability of multiple rows of leads.

Embodiments of the invention are particularly advantageous in area mounting type semiconductor device configurations such as, for example, quad flat pack no-lead (QFN), small-outline no leads (SON) leadless packages have connections made to the devices via contacts on the bottom side of the component to the surface of the connecting substrate of the printed circuit board (PCB). In these type of devices, half etching lead frames are used. With embodiments of the invention, the lead and flag between each unit are connected by saw street for reasons discussed above for preservation of saw blade life, and the lead frame saw street was made to reach half etch. Additionally, the etching lead frame has a relatively higher cost than the stamping lead frame that is in accordance with embodiments of the invention. By adding the taping process in lead frame stamping allows for individual units to be made by punching or stamping and placed directly on the support such as tape. In this process, the support eliminates any requirement or need for the saw street metal, and also reduces the saw blade wearing out during saw singulation process.

Accordingly, in view of these advantages, the packaging cost has been minimized. The stamping lead frame has 60-70% cost down than etching lead frame. Packaging cost during saw singulation process can be reduced. In the process of embodiments, by removing the taping process, the saw singluation machine is able to use a single cut mode.

It will be appreciated that embodiments may be implemented in other devices such as all quad flat pack no-lead (QFN)/power quad flat pack no-lead (PQFN) products.

Add taping process in stamping lead frame procedure. The stamping process make the lead and flag for individual unit, then individual unit was attached on the tape. When the taped stamping lead frame reach assembly factory, and go through die bond wire bond, molding and saw singluation. Because there is no metal in saw street, the saw blade life will increase.

Currently, Multiple Array lead frames for Quad Flat No-lead (QFN) packages use a half-etched lead frame. The lead and flag between each unit are connected by a saw street. For preventing high temperatures during saw singulation, which will cause the saw blade to wear quickly, the lead frame saw street was half-etched. The normal, stamped type lead frame could not reach half etch. The etched lead frame has a higher cost than the stamped lead frame. Add the taping process in lead frame stamping which purpose is making the individual unit directly put on the tape to eliminate the saw street metal, to reduce the saw blade wearing out during the saw singulation process, the packaging cost was reduced thereafter.

By adding the taping process in lead frame stamping process, no metal saw street lead frame is required as with current conventional lead frame design. Thus the saw blade life and machine in saw singulation is increased in particular with QFN type ICs. Also, the taped stamping lead frame contributes to the overall semiconductor device lower packaging cost, and lower cost of lead frame as less metal is required for use in the lead frame. Lead count can also be increase as multiple rows of leads may be easily designed and applied, which also contributes to minimizing packaging costs. Advantageously, the package is a “green” package that limits any environmental impact in that no Pb plating process is required.

While embodiments of the invention have been described and illustrated, it will be understood by those skilled in the technology concerned that many variations or modifications in details of design or construction may be made without departing from the present invention.

1. A method of fabricating a lead frame, the method comprising:
stamping a lead frame material into a desired lead frame configuration, the lead frame configuration including a plurality of leads and a die flag; and
supporting the stamped lead frame configuration with a support material.

2. The method of claim 1, further comprising adhering the stampled lead frame configuration to the support material.

3. The method of claim 1, wherein the support material is adhesive tape.

4. The method of claim 3 wherein the adhesive tape is silicon tape or acrylic tape.

5. A method of assembling a plurality of semiconductor packages, comprising:
forming a plurality of lead frames by stamping a lead frame material into a plurality of desired lead frame configurations, each lead frame configuration including a plurality of leads and a die flag;
supporting the stamped lead frames configurations with a support material;
bonding a corresponding plurality of semiconductor dies to the plurality of lead frame die flags;
wire bonding with wires the semiconductor dies to the leads of respective lead frame configurations;
molding the lead frame configurations, semiconductor dies, and wires to form the plurality of semiconductor packages;
removing the support material; and
separating the plurality of semiconductor packages via saw singulation.

6. The method of claim 5, further comprising adhering lead frame configurations to the support material.

7. The method of claim 5, wherein the support material is adhesive tape.

8. The method of claim 7, wherein the adhesive tape is silicon tape or acrylic tape.

9. A lead frame for a semiconductor package, comprising:
a lead frame configuration formed by stamping a lead frame material; and
a supporting material to support the lead frame configuration.

10. The lead frame of claim 9, wherein the support material is adhesive tape.

11. The lead frame of claim 10, wherein the adhesive tape is silicon tape or acrylic tape.
